(19) United States
(12) Patent Application Publication
(10) Pub. No.: US 2011/0128703 A1
(43) Pub. Date: Jun. 2, 2011

(54) ELECTRONIC DEVICE

(76) Inventors: Mikine Fujihara, Fukaya-shi (JP); Katsuya Kudo, Fukaya-shi (JP)

(21) Appl. No.: 12/941,797

(22) Filed: Nov. 8, 2010

(30) Foreign Application Priority Data
Nov. 30, 2009 (JP) JP 2009-272689

(51) Int. Cl. H05K 7/20

(52) U.S. Cl. 361/697; 361/695

(57) ABSTRACT

According to one embodiment, an electronic device includes a board housed in a housing, a plurality of first modules mounted on the board and a second module. The first modules generating heat while in operation are mounted on the board at intervals while projecting from the board, and the first modules are arranged to be adjacent to each other inside the housing. At least one air flow path is formed between an adjacent pair of first modules. The second module is placed adjacent to one end side of the first modules across the air flow path and has a projecting height from the board lower than that of the first modules. A fan is housed in the housing. The fan creates an air flow inside the housing from the first modules towards the second module.

### CROSS-REFERENCE TO RELATED APPLICATIONS

This application is based upon and claims the benefit of priority from Japanese Patent Application No. 2009-272689, filed Nov. 30, 2009; the entire contents of which are incorporated herein by reference.

### FIELD

Embodiments described herein relate generally to an electronic device comprising a plurality of first modules which generate heat and a second module connected to the first modules, and more specifically, a structure which assure a ventilation property between each adjacent pair of first modules.

### BACKGROUND

Electronic devices are known, which can record a plurality of television programs at the same time, or a long-duration program, and these devices are connected to television sets when they are used.

An electronic device of the above-described type comprises a box-shaped housing, inside of which a plurality of electronic parts are contained. Specific ones of the electronic parts have a high power consumption, and these ones naturally have a large amount of heat generation. Therefore, conventionally, these specific electronic parts are compulsory cooled down by a fan.

For example, Jpn. Pat. Appln. KOKAI Publication No. 2007-102671 discloses an electronic device in which a plurality of heat-generating electronic parts are arranged within the range of blow of cool wind generated by the fan. These electronic parts are arranged in a line crossing the central axial line of an impeller of the fan. A gap is provided between each pair of adjacent electronic parts.

With the above-described structure, as the impeller of the fan is rotated, cool wind generated by the fan is blown onto the electronic parts, and passes through the gap between adjacent electronic parts of each pair. In this manner, the plurality of electronic parts are cooled down by a common fan.

In the electronic device disclosed in Jpn. Pat. Appln. KOKAI Publication No. 2007-102671, the cool wing blown from the fan cools down the electronic parts, and then is released to the outside of the housing from a plurality of vents made in the housing. In other words, with the structure of this electronic device, other parts do not intervene between the electronic parts blown by the cool wind and the vents made in the housing, but the gaps created between adjacent electronic parts face the respective vents.

In the case where other parts intervene between the electronic parts blown by the cool wind and the vents made in the housing, the flow of the cool wind passing through each pair of adjacent electronic parts is blocked by these parts. In this case, heat is easily kept between the adjacent electronic parts of each pair.

As described above, Jpn. Pat. Appln. KOKAI Publication No. 2007-102671 does not make any assumption for the case where the ventilation between adjacent electronic parts is degraded when some other parts are located on the downstream side of the heat-generating electronic parts along the direction of the flow of the cool wind. Therefore, with this conventional technique, there are chances that heat is regionally accumulated between electronic parts. Thus, there is a further possibility still remaining to be improved for enhancing the heat radiation property of the electronic parts.

### BRIEF DESCRIPTION OF THE DRAWINGS

A general architecture that implements the various feature of the embodiments will now be described with reference to the drawings. The drawings and the associated descriptions are provided to illustrate the embodiments and not to limit the scope of the invention.

FIG. 1 is an exemplary perspective view of a television external device according to the first embodiment;

FIG. 2 is an exemplary cross sectional view schematically showing the structure inside of the television external device according to the first embodiment;

FIG. 3 is an exemplary cross sectional view of the television external device according to the first embodiment, schematically showing the air flow inside the housing;

FIG. 4 is an exemplary rear view schematically showing the structure inside of the television external device according to the first embodiment;

FIG. 5 is an exemplary cross sectional view of the television external device according to the first embodiment, showing the positions of the third circuit board containing a tuner module and a distributor, and a centrifugal fan in relation to each other;

FIG. 6 is an exemplary perspective view of the third circuit board according to the first embodiment, showing the positions of six tuner modules and a distributor mounted on the third circuit board in relation to each other;

FIG. 7 is an exemplary side view of the third circuit board according to the first embodiment, showing the positions of the tuner modules and the distributor in relation to each other;

FIG. 8 is an exemplary front view of the third circuit board according to the first embodiment, showing the positions of the six tuner modules and the distributor in relation to each other as viewed from the direction of arrow F8 in FIG. 7;

FIG. 9 is an exemplary cross sectional decomposed view of the tuner module in the first embodiment, showing the positions of chassis which support the board, the first side cover and the second side cover in relation to each other;

FIG. 10 is an exemplary cross sectional view of the tuner module according to the first embodiment;

FIG. 11 is an exemplary cross sectional view schematically showing the structure inside of the television external device according to the second embodiment;

FIG. 12 is an exemplary side view of the third circuit board according to the second embodiment, showing the positions of tuner modules, a distributor and a heat conductive plate in relation to each other;

FIG. 13 is an exemplary front view of the third circuit board according to the second embodiment, showing the positions of the six tuner modules, the distributor and the heat conductive plate in relation to each other as viewed from the direction of arrow F13 in FIG. 12;

FIG. 14 is an exemplary cross sectional view schematically showing the structure inside of the television external device according to the third embodiment;

FIG. 15 is an exemplary side view of the third circuit board according to the third embodiment, showing the positions of tuner modules, a distributor and a heat sink in relation to each other;

FIG. 16 is an exemplary cross sectional view taken along the line F16-F16 in FIG. 15;

FIG. 17 is an exemplary cross sectional view schematically showing the structure inside of the television external device according to the fourth embodiment; and

FIG. 18 is an exemplary side view of the third circuit board according to the fourth embodiment, showing the positions of tuner modules, a distributor and a heat conductive plate including a heat sink, in relation to each other.

### DETAILED DESCRIPTION

Various embodiments will be described hereinafter with reference to the accompanying drawings.

In general, according to one embodiment, an electronic device includes a board housed in a housing, a plurality of first modules mounted on the board and a second module. The first modules generating heat while in operation are mounted on the board at intervals while projecting from the board, and the first modules are arranged to be adjacent to each other inside the housing. At least one air flow path is formed between an adjacent pair of first modules. The second module is placed adjacent to one end side of the first modules across the air flow path and has a projecting height from the board lower than that of the first modules. A fan is housed in the housing. The fan creates an air flow inside the housing from the first modules towards the second module.

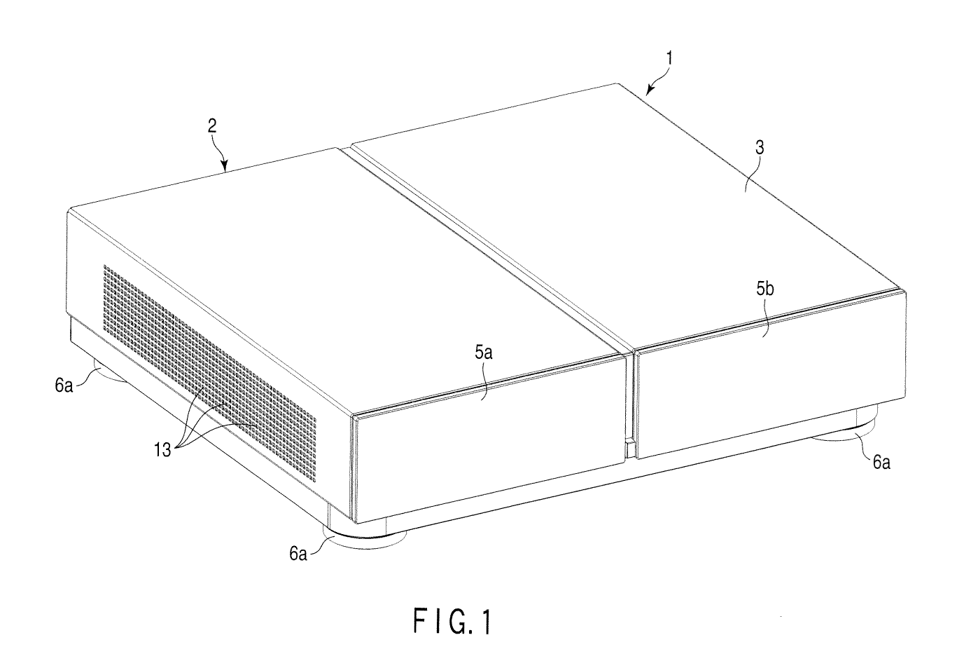

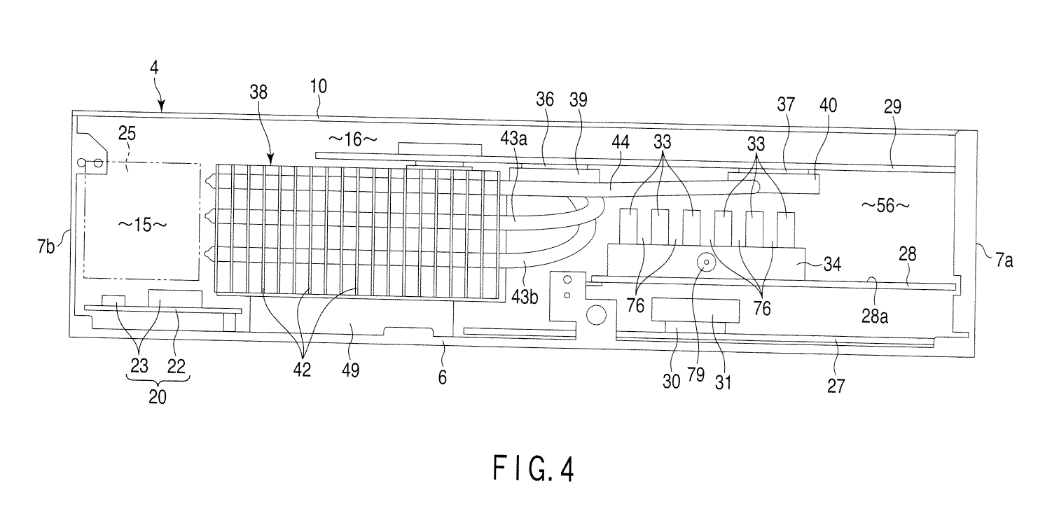

The first embodiment will now be described with reference to FIGS. 1 to 10.

FIG. 1 shows a television external device 1, which is an example of the electronic device. The television external device 1 is connected to, for example, a liquid crystal television when the device is used. The television external device 1 has, for example, a function of receiving various types of television programs and also a function of recording a plurality of television programs at the same time or recording a long-duration program.

The television external device 1 comprises a flat box-shaped main body 2. The main body 2 of the device includes a metal-made housing 4 covered by a decorated cover 3, and left-side and right-side front doors 5a and 5b which cover the front face of the decorated cover 3.

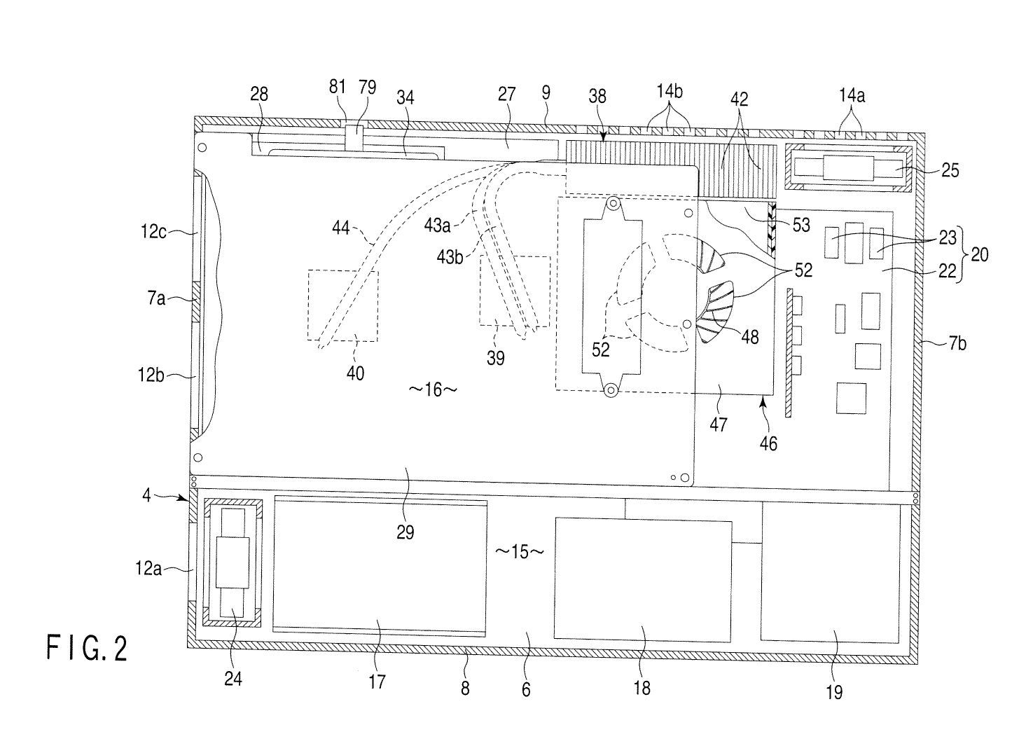

As shown in FIGS. 2 to 5, the housing 4 is a framework of the main body 2. The housing 4 comprises a bottom plate 6, left and right side plates 7a and 7b, a front plate 8, a back plate 9 and a top plate 10. The bottom plate 6 has a rectangular plate shape having four corner portions. Legs 6a are attached respectively to the corner portions of the bottom plate 6 and the legs 6a are placed on, for example, a television table. A plurality of air intakes 11 are made in the central portion of the rear half of the bottom plate 6.

The side plates 7a and 7b, the front plate 8 and back plate 9 stand up from the circumferential edges of the bottom plate 6. The left side plate 7a comprises first to third air inlets 12a, 12b and 12c. The first to third air inlets 12a, 12b and 12c are arranged in line at intervals in the depth direction of the housing 4, and these holes are communicated to the outside of the main body 2 via a plurality of air holes 13 made in the decorated cover 3.

The back plate 9 comprises a plurality of first air outlets 14a and a plurality of second air outlets 14b in its right half region. Further, the top plate 10 is placed across the upper edges of the left and right side plates 7a and 7b, front plate 8 and back plate 9, and also faces the bottom plate 6.

As shown in FIG. 2, the housing 4 comprises a first container region 15 and a second container region 16. The front half portion of the first container region 15 extends in the width direction of the housing 4 along the front plate 8 of the housing 4. The rear half portion of the first container region 15 extends in the depth direction of the housing 4 along the right side plate 7b of the housing 4. The first air inlet 12a of the side plate 7a is communicated to the left end of the front half portion of the first container region 15. The first air outlet 14a of the back plate 9 is communicated to the rear end of the rear half portion of the first container region 15.

The second container region 16 is surrounded by the left side plate 7a and the back plate 9 of the housing 4, and also located behind the front half portion of the first container region 15. The air intakes 11 of the bottom plate 6 are communicated to the right end portion of the second container region 16. The second and third air inlets 12b and 12c of the side plate 7a are communicated to the left end portion of the second container region 16.

As shown in FIG. 2, a first data memory module 17, a second data memory module 18, a card connection unit 19 and a power module 20 are contained in the first container region 15 of the housing 4.

The first and second data memory modules 17 and 18 are designed to record television programs and quickly search through a recorded television program for playback. The first and second data memory modules 17 and 18 each comprise a plurality of hard disk drive units.

The card connection unit 19 comprises six card slots for six B-CAS cards to be inserted, for receiving, for example, terrestrial digital television/BS digital broadcastings. The first data memory module 17, the second data memory module 18 and the card connection unit 19 are disposed in the front half portion of the first container region 15 and arranged in line in the width direction of the housing 4.

The power module 20 comprises a first circuit board 22 which is an example of a power source board. The first circuit board 22 is secured to the right end portion of the bottom plate 6 of the housing 4. On the first circuit board 22, a plurality of circuit parts 23 are mounted, which forms the power circuit. The circuit parts 23 are disposed in the rear half portion of the first container region 15.

A first axial fan 24 is located on the left end of the front half portion of the first container region 15. The first axial fan 24 is set to face the first air inlet 12a. Further, a second axial fan 25 is located on the rear end of the rear half portion of the first container region 15. The second axial fan 25 is set to face the first air outlet 14a, and it compulsorily discharges mainly the air in the first container region 15 to the outside of the housing 4.

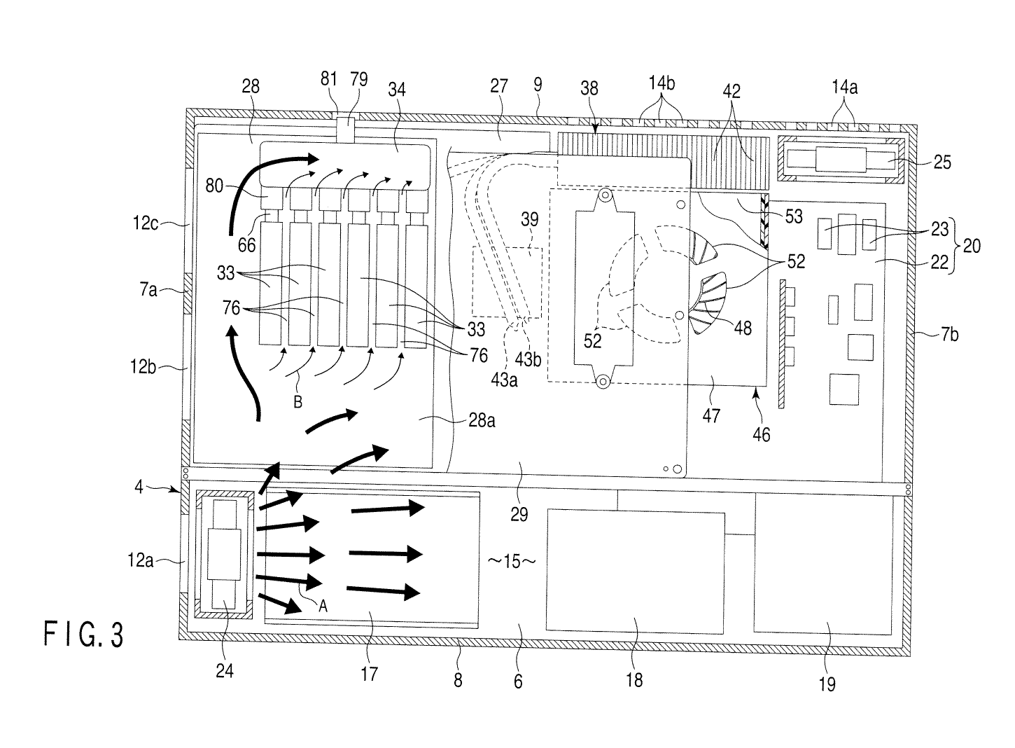

When the first axial fan 24 and the second axial fan 25 are driven, the air outside the housing 4 is suctioned from the first air inlet 12a into the front half portion of the first container region 15 as indicated by the thick solid arrow in FIG. 3. A portion of the air suctioned into the front half portion of the first container region 15 flows into the second container region 16. At the same time, the air in the rear half portion of the first container region 15 is discharged from the first air outlet 14a to the outside of the housing 4.

As shown in FIGS. 2 to 5, second to fourth circuit boards 27, 28 and 29 are contained in the second container region 16 of the housing 4. The second to fourth circuit boards 27, 28 and 29 are stacked at intervals in the thickness direction of the housing 4.

The second circuit board 27 is a board for image processing, and is supported horizontally above the bottom plate 6 of the housing 4. A chip part 30 for image processing is mounted on the second circuit board 27. The chip part 30 comprises a heat sink 31.

The third circuit board 28 is a tuner board, and is supported horizontally above the second circuit board 27 via a bracket, which is not shown in the figure. The upper surface of the third circuit board 28 is a flat mount surface 28a. On the mount surface 28a of the third circuit board 28, six tuner modules 33 which receive television signals and one distributor 34 are mounted.

The fourth circuit board 29 is a main board, and is supported horizontally above the third circuit board 28 via a bracket, which is not shown in the figure. A high-performance processor 36 and an I/O controller 37 are mounted on the lower surface of the fourth circuit board 29. The high-performance processor 36 and I/O controller 37 are cooled down in order to maintain its operation temperature at an appropriate level. In this embodiment, the heat generated from the high-performance processor 36 and I/O controller 37 is propagated to the heat sink 38 and released to the outside of the housing 4 from the heat sink 38.

More specifically, as shown in FIGS. 2 to 5, a first heat-receiving block 39 is thermally connected to the high-performance processor 36. The first heat-receiving block 39 is formed of a metal material having an excellent heat conductivity, for example, copper. The first heat-receiving block 39 is held to the lower surface of the fourth circuit board 29 by a metal holder, which is not shown in the figure.

Similarly, a second heat-receiving block 40 is thermally connected to the I/O controller 37. The second heat-receiving block 40 is formed of a metal material having an excellent heat conductivity, for example, copper. The second heat-receiving block 40 is held to the lower surface of the fourth circuit board 29 by a metal holder, which is not shown in the figure.

The heat sink 38 comprises a plurality of radiating fins 42. The radiating fins 42 are arranged in parallel with each other at intervals. The heat sink 38 and the first heat receiving block 39 are thermally connected to each other via two heat pipes 43a and 43b. With this structure, the heat generated from the high-performance processor 36 is propagated to the first heat receiving block 39, and then transferred to the heat sink 38 via the two heat pipes 43a and 43b.

Similarly, the heat sink 38 and the second heat receiving block 40 are thermally connected to each other via one heat pipe 44. With this structure, the heat generated from the I/O controller 37 is propagated to the second heat receiving block 40, and then transferred to the heat sink 38 via the heat pipe 44.

Further, the three heat pipes 43a, 43b and 44 hold the heat sink 38 to the rear end portion of the lower surface of the fourth circuit board 29. Thus, while the fourth circuit board 29 is supported horizontally above the third circuit board 28, the heat sink 38 is contained in the rear end portion of the second container region 16 of the housing 4, and set to face the second air outlet 14b of the housing 4.

As shown in FIGS. 2, 3 and 5, a centrifugal fan 46 is disposed in the second container region 16 of the housing 4. The centrifugal fan 46 is disposed on the right side of the second and third circuit boards 27 and 28, and blows cool air towards the heat sink 38.

The centrifugal fan 46 comprises a fan casing 47 and an impeller 48. A cylindrical duct portion 49 is formed in the bottom of the fan casing 47. The duct portion 49 projects from the bottom of the fan casing 47 towards the bottom plate 6 of the casing 4, and an end portion thereof is secured to the bottom plate 6.

Further, the duct portion 49 surrounds the region of the bottom plate 6 where the air intakes 11 are opened. With this structure, the duct portion 49 of the fan casing 47 forms a first air inlet 50 communicated to the outside of the housing 4 via the air intakes 11.

A impeller mount portion 51 and four second air inlets 52 are formed in the upper wall of the fan casing 47. The impeller mount portion 51 is disposed in the central portion of the upper wall. The second air inlets 52 are arranged at intervals therebetween such as to surround the impeller mount portion 51.

Further, the fan casing 47 comprises an air outlet 53. The air outlet 53 is opened between the first air inlet 50 and the second air inlets 52 and towards the rear side of the housing 4, and the air outlet 53 faces the heat sink 38.

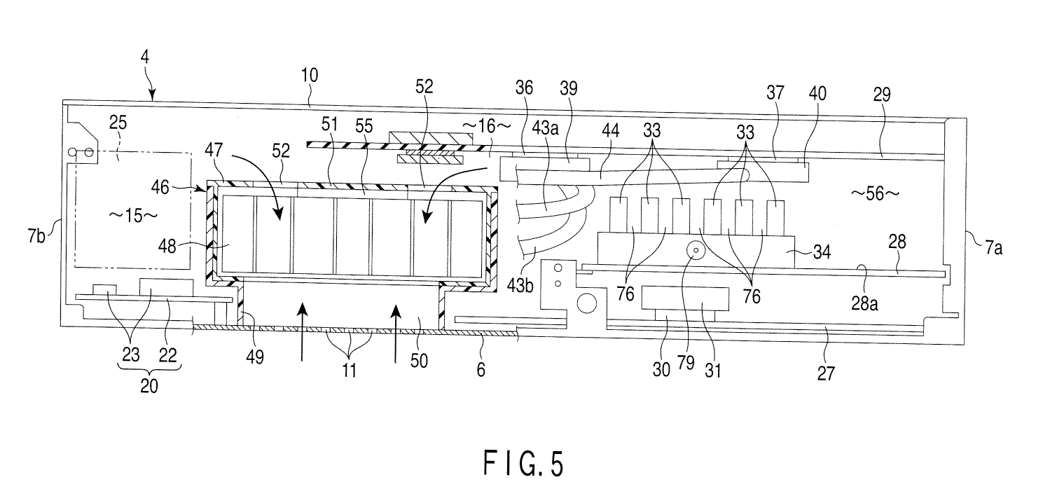

As shown in FIG. 5, the impeller 48 is supported on the lower surface of the impeller mount portion 51 via a flat motor 55. The impeller 48 is disposed between the first air inlet 50 and the second air inlets 52. The outer circumferential portion of the impeller 48 faces the air outlet 53.

In this embodiment, the fourth circuit board 29 is built out upwards from the centrifugal fan 46. In this manner, a part of the second air inlets 52 are opened to a gap 56 located between the third circuit board 28 and the fourth circuit board 29.

When the impeller 48 is driven by the flat motor 55, air outside the housing 4 is suctioned into the central portion of rotation of the impeller 48 via the air intakes 11 and the first air inlet 50 as indicated by the arrows in FIG. 5. Along with this air flow, the air inside the housing 4 is suctioned into the central portion of rotation of the impeller 48 via the second air inlet 52. As a result, the air flow towards the centrifugal fan 46 is created in the gap 56 as well located between the third circuit board 28 and the fourth circuit board 29.

The six tuner modules 33 and the distributor 34 mounted on the third circuit board 28 are cooled down by the air flowing through the gap 56 located between the third circuit board 28 and the fourth circuit board 29. In this embodiment, the six tuner modules 33 each are an example of the first module which generates heat while in operation, and each of them has a flat and slim box shape.

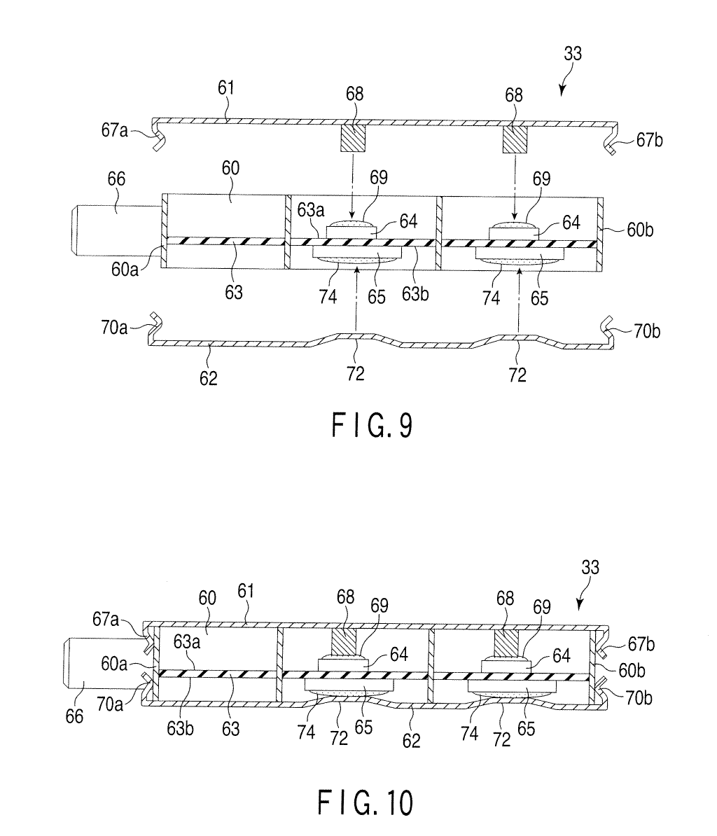

FIGS. 9 and 10 each show one tuner module 33 as a typical example. The tuner module 33 comprises a chassis 60 and the first side cover 61 and the second side cover 62. The chassis 60 and the first side cover 61 and the second side cover 62 are each formed of a metal material having an excellent heat conductivity, for example, a plated steel plate (iron) or aluminum.

The chassis 60 comprises a front panel 60a and a rear panel 60b. The front panel 60a and rear panel 60b are apart from each other in the longitudinal direction of the tuner module 33. A circuit board 63 is supported between the front panel 60a and the rear panel 60b.

The circuit board 63 comprises a first surface 63a and a second surface 63b located on the opposite side to the first surface 63a. On the first surface 63a of the circuit board 63, a plurality of first circuit parts 64 are mounted. Similarly, a plurality of second circuit parts 65 are mounted on the second surface 63b of the circuit board 63. The first and second circuit parts 64 and 65 each are an example of the heat generating members which generates heat while in operation.

A coaxial connector 66 is attached to the front panel 60a of the chassis 60. The coaxial connector 66 is electrically connected to the circuit board 63, and is projected from the chassis 60.

The first side cover 61 comprises a pair of stopper pieces 67a and 67b. The stopper pieces 67a and 67b are apart from each other in the longitudinal direction of the tuner module 33. The stopper pieces 67a and 67b are detachably hooked on the outer surface of the front panel 60a and the outer surface of the rear panel 60b of the chassis 60. With this structure, the first side cover 61 is held to the chassis 60 while covering the chassis 60 from one side along the thickness direction of the chassis 60.

As shown in FIGS. 9 and 10, a plurality of heat conductive blocks 68 are mounted on the inner surface of the first side cover 61. The heat conductive blocks 68 are each formed of a metal material having an excellent heat conductivity, for example, aluminum. The heat conductive blocks 68 are each thermally connected to the first circuit parts 64, respectively, via heat-conductive grease 69 applied on the first circuit parts 64. With this structure, the heat generated from the first circuit parts 64 is propagated to the first side cover 61 via the heat-conductive grease 69 and the heat-conductive blocks 68.

The second side cover 62 comprises a pair of stopper pieces 70a and 70b. The stopper pieces 70a and 70b are apart from each other in the longitudinal direction of the tuner module 33. The stopper pieces 70a and 70b are detachably hooked on the outer surface of the front panel 60a and the outer surface of the rear panel 60b of the chassis 60 from the opposite side with respect to the first side cover 61. With this structure, the second side cover 62 is held to the chassis 60 while covering the chassis 60 from the other side along the thickness direction of the chassis 60.

The second side cover 62 comprises a plurality of recess portions 72 which recess towards the chassis 60. The recess portions 72 are formed at positions corresponding to the second circuit parts 65. The inner surface of each of the recess portions 72 is thermally connected to the respective one of the second circuit parts 65 via heat-conductive grease 74 applied onto the second circuit parts 65. With this structure, the heat generated from the second circuit parts 65 is propagated to the second side cover 62 via the heat-conductive grease 74.

Thus, the outer surfaces of the first and second side covers 61 and 62 have a function of a heat radiating surface to release the heat of the first and second circuit parts 64 and 65 to the outside of the tuner module 33.

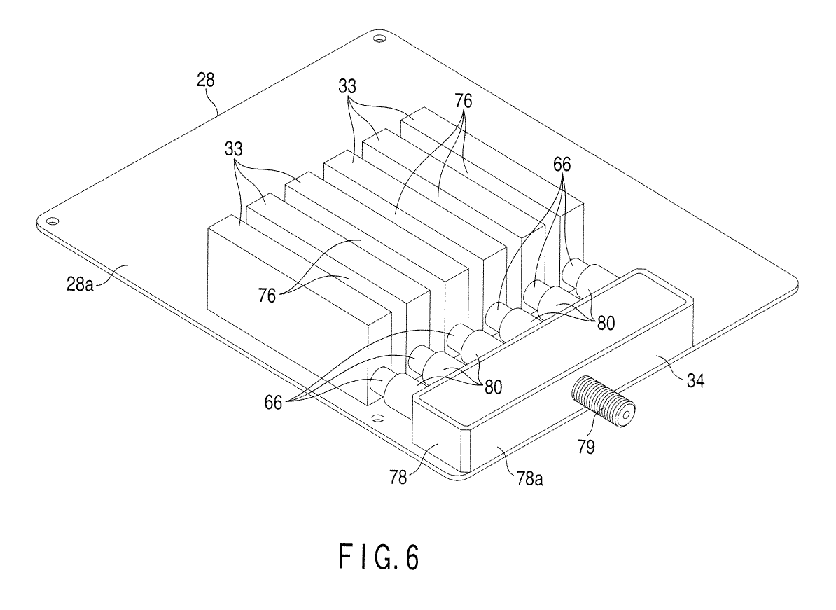

As shown in FIG. 6, the six tuner modules 33 are secured to the mount surface 28a of the third circuit board 28 each in such a posture that each stands up longitudinally from the mount surface 28a. With this structure, the six tuner modules 33 are projected upwards from the mount surface 28a. Further, the tuner modules 33 are held on the mount surface 28a such as to extend towards the depth direction of the housing 4. The coaxial connector 66 projecting out from the chassis 60 faces the rear side of the housing 4.

The six tuner modules 33 are arranged in line at intervals in the width direction of the housing 4. With this arrangement, five air flow paths 76 are each formed between an adjacent pair of tuner modules 33. Each of the air flow paths 76 extends straight in the depth direction of the housing 4. The air flow paths 76 are opened to the gap 56 between the third circuit board 28 and the fourth circuit board 29. Further, the first and second side covers 61 and 62 of the tuner modules 33 are exposed to the air flow paths 76.

On the other hand, the distributor 34 supplies television signals to the six tuner modules 33, respectively. In this embodiment, the distributor 34 is an example of the second module. The distributor 34 comprises a metal-made case 78, one cable connector terminal 79 and six outlets 80.

The case 78 has a flat and slip box shape. The case 78 comprises a first end surface 78a and a second end surface 78b located on the opposite side to the first end surface 78a. The cable connector terminal 79 is to be connected an antenna cable, which is not shown in the figure, and it projects from the first end surface 78a to the outside of the case 78. Further, the cable connector terminal 79 is located at the center along the longitudinal direction of the case 78.

To each of the outlets 80, the coaxial connector 66 of each of the tuner modules 33 is removable fit. The outlets 80 project from the second end surface 78b to the outside of the case 78. Further, the outlets 80 are arranged in line on the second end surface 78b at intervals.

The distributor 34 have the above-described structure is held on the mount surface 28a of the third circuit board 28 in such a posture that it is placed horizontally along the mount surface 28a. The distributor 34 is disposed behind the six tuner modules 33. Further, the distributor 34 extends in the width direction of the housing 4 such as to normally cross with the longitudinal direction of the six tuner modules 33. The distributor 34 is placed next to the end portions of the tuner modules 33 such as to set across the opening ends of the air flow paths 76.

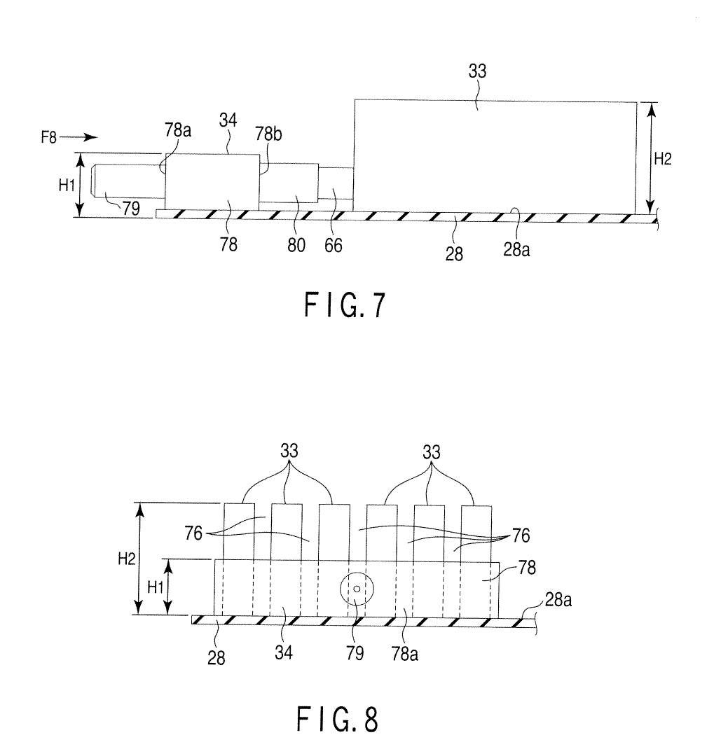

With the above-described structure, the projecting height H1 of the distributor 34 with respect to the mount surface 28a of the third circuit board 28 is lower than the projecting height H2 of the tuner module 33 with respect to the mount surface 28a of the third circuit board 28 as shown in FIGS. 7 and 8. Consequently, when the third circuit board 28 is viewed from behind the housing 4, the upper half portions of the air flow paths 76 located between adjacent pairs of tuner modules 33 are exposed towards the rear side of the housing without being blocked by the distributor 34.

The cable connector terminal 79 of the distributor 34 projects from the rear side of the case 78, and it faces a cable plug-in 81 opened in the back plate 9 of the housing 4. Further, the outlets 80 of the distributor 34 project towards the tuner modules 33, and they are fit to the coaxial connectors 66 of the tuner modules 33, respectively. With this structure, the six tuner modules 33 are electrically connected to the distributor 34, and thus television signals are supplied to the tuner modules 33 from the distributor 34. Further, in this embodiment, the intervals between the six tuner modules 33 are narrowed in order to mainly preventing the attenuation of the television signals and to keep the mount region of the tuner modules 33 small with respect to the area of the mount surface 28a.

In the television external device 1 having the above-described structure, the six tuner modules 33 mounted on the third circuit board 28 each comprise the first and second circuit parts 64 and 65 which generate heat while in operation. The heat generated from the first and second circuit parts 64 and 65 is propagated to the first and second side covers 61 and 62. Then, the heat is released from the outer surfaces of the first and second side covers 61 and 62 to the gap 56 between the third circuit board 28 and the fourth circuit board 29.

Further, the distributor 34 generates heat when supplying television signals to the tuner modules 33. The heat generated from the distributor 34 is released from the outer surface of the case 78 to the gap 56 between the third circuit board 28 and the fourth circuit board 29. In this embodiment, the amount of heat generated by the distributor 34 is less that that of the tuner modules 33. Therefore, the temperature of the distributor 34 is kept lower than that of the tuner modules 33.

As described above, the heat of the tuner modules 33 is diffused from the coaxial connectors 66 to the case 78 of the distributor 34 via the outlets 80, and also released from the outer surface of the case 78 to the gap 56.

When the first axial fan 24 is driven while the television external device 1 is being used, the air outside the housing 4 is suctioned from the first air inlet 12a into the front half portion of the first container region 15 as indicated by the thick solid arrow in FIG. 3. A portion of the air suctioned into the front half portion of the first container region 15 flows into the second container region 16.

When the second axial fan 25 is driven, the air inside the housing 4 is discharged through the first air outlet 14a to the outside of the housing 4. Further, when the centrifugal fan 46 is driven, the air inside the housing 4 is suctioned via the second air inlet 52. As a result, the air flow towards the centrifugal fan 46 from the first air inlet 12a is created in the gap 56 located between the third circuit board 28 and the fourth circuit board 29.

The air flowing through the gap 56 passes around the tuner modules 33 and the distributor 34, and thus the tuner modules 33 and the distributor 34 are cooled down. Further, a portion of the air flowing through the gap 56 is guided to the air flow paths 76 each formed between a respective adjacent pair of tuner modules 33, as indicated by thin solid arrow B in FIG. 3. The air guided to the air flow paths 76 is allowed to flow towards the distributor 34 along the air flow paths 76.

The distributor 34 is located on the downstream side to the tuner modules 33 along the air flow direction, and it is mounted on the mount surface 28a of the third circuit board 28 in such a posture that it is placed horizontally along the mount surface 28a. With the above-described structure, the projecting height H1 of the distributor 34 with respect to the mount surface 28a is kept lower than the projecting height H2 of the tuner module 33 with respect to the mount surface 28a. Consequently, the downstream ends of the air flow paths 76 are not blocked by the distributor 34.

As a result, the air guided by the air flow paths 76 flows smoothly towards the distributor 34, and thus the air flow in the air flow paths 76 is not blocked by the distributor 34. The first and second side covers 61 and 62 of the tuner modules 33 exposed to the air flow paths 76 are directly exposed to the air flow. In this manner, the heat of the first and second circuit parts 64 and 65 propagated to the first and second side covers 61 and 62 is efficiently released onto the air flow.

According to the first embodiment, an excellent ventilation is achieved in the air flow paths 76 each defined between an adjacent pair of tuner modules 33. Consequently, it is possible to avoid the heat released from the first and second side covers 61 and 62 of the tuner modules 33 from remaining in the air flow paths 76. In this manner, the heat radiating performance of the tuner modules 33 is enhanced by utilizing the air flowing in through the gap 56 located between the third circuit board 28 and the fourth circuit board 29.

In other words, the tuner modules 33 are efficiently cooled down without forcibly supplying air to the air flow paths 76 or creating a strong air flow by the air flow paths 76. Thus, this embodiment exhibits such an advantage that with a little flow of air, the heat of the tuner modules 33 is efficiently radiated.

The invention is not limited to first embodiment, but it can be modified into various versions as long as the essence of the invention falls within its scope.

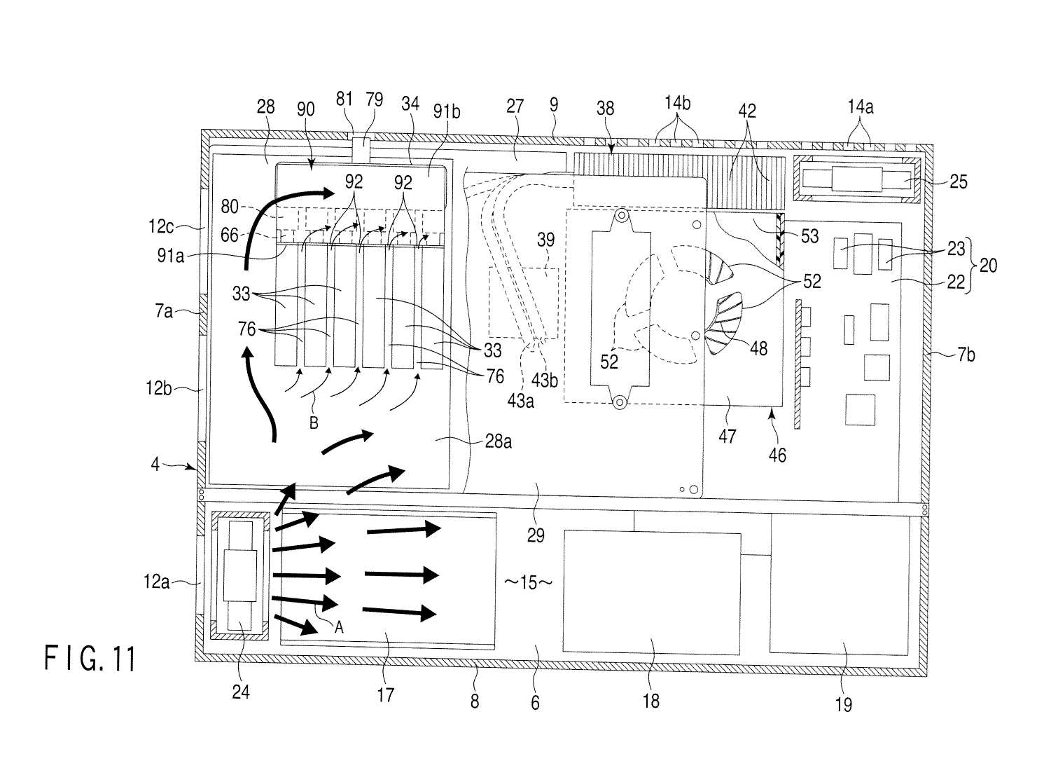

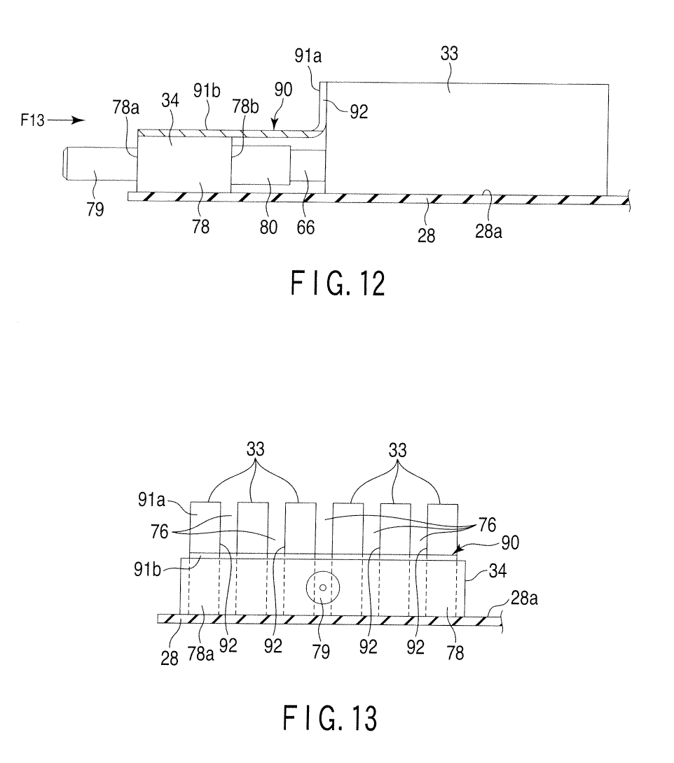

For example, FIGS. 11 to 13 show the second embodiment.

The second embodiment is different from the first embodiment described above in the respect that the six tuner modules 33 and the distributor 34 are thermally connected to each other via a heat conductive plate 90. The rest of the structure is similar to that of the first embodiment. In the second embodiment, the same structural parts as those of the first embodiment will be designated by the same reference numerals, and detailed descriptions therefore will be omitted.

As shown in FIGS. 11 to 13, the total length of the six tuner modules 33 arranged is substantially the same as the entire length of the distributor 34. The heat conductive plate 90 is an example of the thermal conductive member, and it is formed of a metal material having an excellent heat conductivity, for example, aluminum. The heat conductive plate 90 has substantially the same width dimension as the entire length of the distributor 34. The heat conductive plate 90 is provided across between the upper surface of the distributor 34 and the rear end surfaces of the six tuner modules 33.

The heat conductive plate 90 comprises the first portion 91a which is vertically formed and the second portion 91b which is horizontally formed. The first portion 91a is set to abut against the rear ends of the six tuner modules 33. The first portion 91a is secured to the rear end surfaces of the six tuner modules 33 by fixing means such as screws, and thus the first portion 91a is thermally connected to the six tuner modules 33.

The second portion 91b extends horizontally from the lower end of the first portion 91a towards the distributor 34. The second portion 91b is thermally connected to the distributor 34 as it is stacked on the upper surface of the distributor 34.

It is preferable that a heat conductive sheet or a heat conductive grease should be provided between the first portion 91a of the heat conductive plate 90 and the tuner modules 33, and between the second portion 91b of the heat conductive plate 90 and the distributor 34.

Further, the first portion 91a of the heat conductive plate 90 comprises a plurality of through holes 92. The through holes 92 are made by cutting off the first portion 91a at positions corresponding to the air flow paths 76 each formed between an adjacent pair of tuner modules 33. Thus, the first portion 91a has a comb-like shape and is located on the downstream side to the air flow paths 76 along the air flow direction.

According to the second embodiment, the heat generated from the tuner modules 33 is propagated to the heat conductive plate 90 via the first portion 91a thereof. Similarly, the heat generated from the distributor 34 is propagated to the heat conductive plate 90 via the second portion 91b thereof. In this manner, the heat of the tuner modules 33 and the distributor 34 is dissipated to the heat conductive plate 90, and thus the heat radiation of the tuner modules 33 and the distributor 34 is improved.

Further, the first portion 91a of the heat conductive plate 90 comprises a plurality of through holes 92 made by cutting off the first portion 91a at positions corresponding to the air flow paths 76. The through holes 92 are communicated to the downstream ends of the air flow paths 76. With this structure, the air flowing through the air flow paths 76 is allowed to pass through the through holes 92 of the heat conductive plate 90 and discharged towards the rear side of the tuner modules 33. In this manner, the air flow passing through the air flow paths 76 is not blocked by the heat conductive plate 90.

Moreover, the air having passed the through holes 92 flows to follow along the second portion 91b of the heat conductive plate 90. In this manner, the second portion 91b, which is heated by the heat generated from the distributor 34, is cooled down actively by utilizing the air flow. Thus, the heat radiation of the distributor 34 is improved.

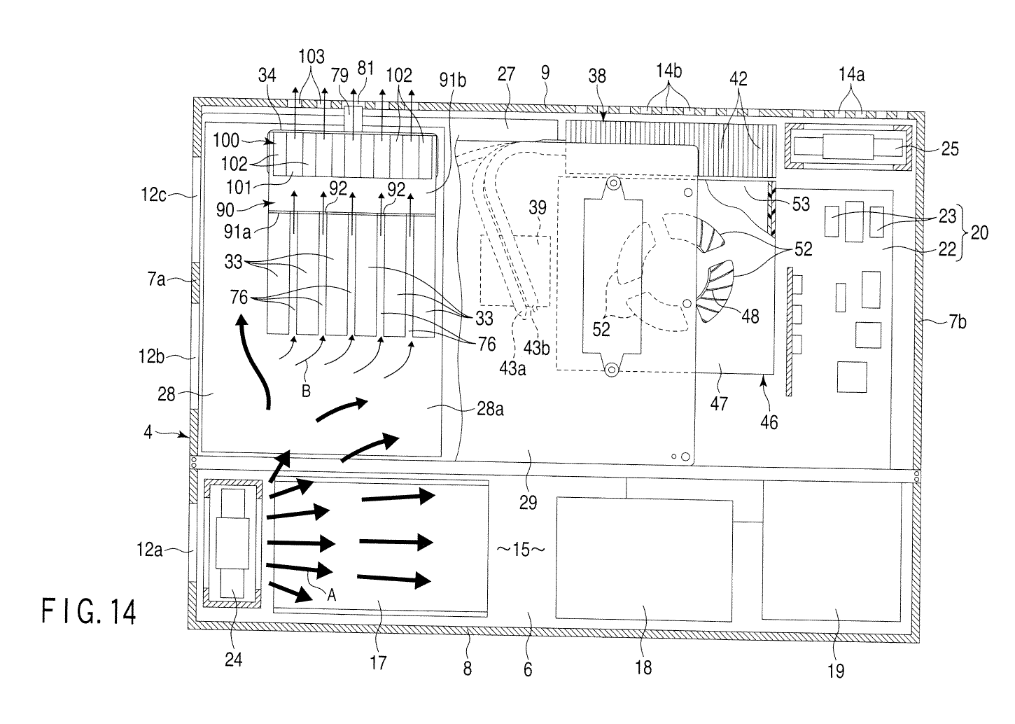

FIGS. 14 to 16 show the third embodiment.

The third embodiment is different from the second embodiment described above in the respect that a heat sink 100 is provided for the second portion 91b of the heat conductive plate 90. The rest of the structure of the third embodiment is similar to that of the second embodiment. In the third embodiment, the same structural parts as those of the second embodiment will be designated by the same reference numerals, and detailed descriptions therefore will be omitted.

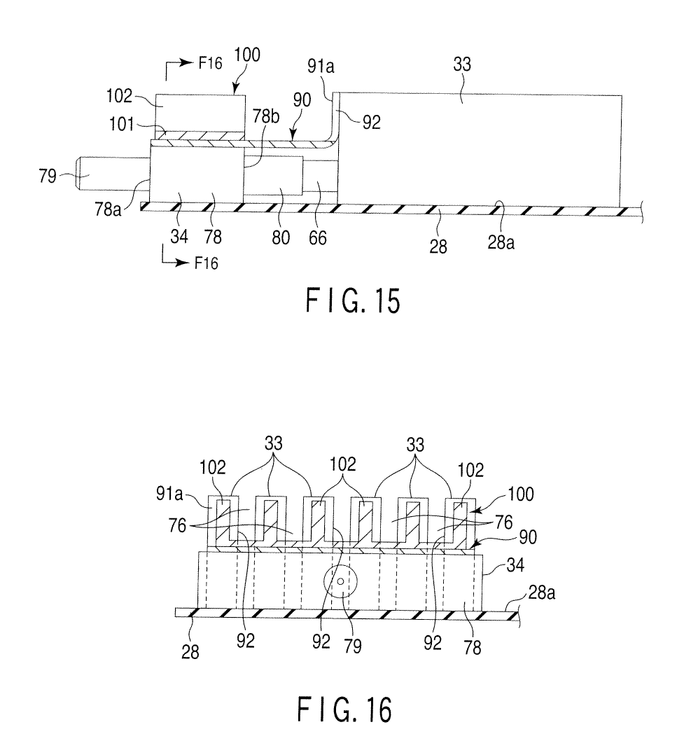

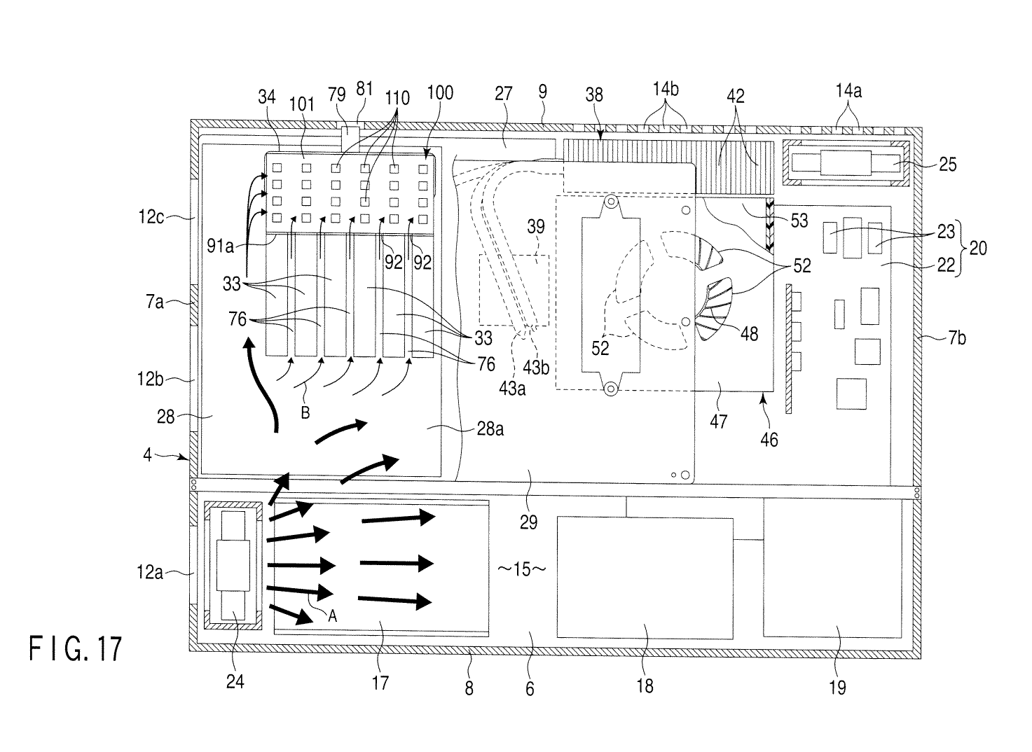

The heat sink 100 is formed of a metal material having an excellent heat conductivity, for example, aluminum. As shown in FIGS. 15 and 16, the heat sink 100 comprises a base 101 and six radiating fins 102.

The base 101 is a flat plate having a size substantially the same as that of the second portion 91b of the heat conductive plate 90. The base 101 is secured to, the upper surface of the second portion 91b via a heat conductive adhesive. The radiating fins 102 project out from the upper surface of the base 101 while being formed as an integral unit therewith. The radiating fins 102 each have a flat plate shape extending in the longitudinal direction of the tuner modules 33. Further, the radiating fins 102 are arranged in line at intervals in the disposing direction of the tuner modules 33 in the downstream of the through holes 92 of the heat conductive plate 90 along the air flow direction.

In this embodiment, the radiating fins 102 are each formed to be narrower in width than that of the tuner modules 33 and also located in the rear side of the tuner modules 33, so as not to block the air flow after passing through the air flow paths 76.

According to the third embodiment, the heat of the tuner modules 33 and the distributor 34 propagated to the heat conductive plate 90 is released to the inside of the housing 4 via the heat sink 100.

Moreover, the radiating fins 102 of the heat sink 100 are disposed in the rear side of the tuner modules 33. With this structure, the air flow passing through the air flow paths 76 is not blocked by the radiating fins 102.

Further, the air flow having passed the air flow paths 76 then passes around the radiating fins 102, and thus the radiating fins 102 are exposed directly to the air flow. In this manner, the heat of the heat conductive plate 90 propagated to the radiating fins 102 is efficiently released onto the air flow, and therefore the heat radiation of the heat conductive plate 90 can be enhanced.

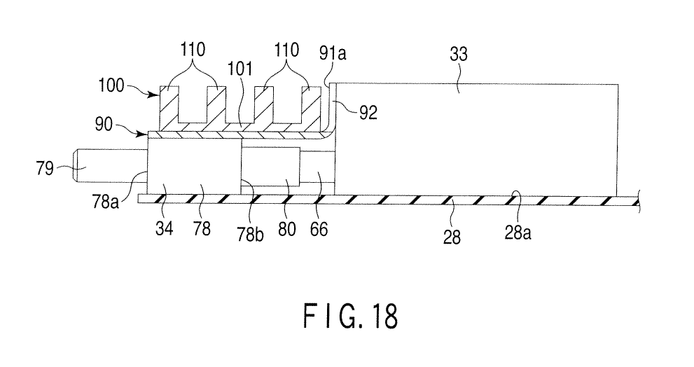

FIGS. 17 and 18 show the fourth embodiment.

The fourth embodiment is different from the third embodiment described above in the structure of the heat sink 100. The rest of the structure of the fourth embodiment is basically similar to that of the third embodiment.

As shown in FIGS. 17 and 18, the heat sink 100 comprises a plurality of prism heat radiating projections 110. The heat radiating projections 110 project out from the upper surface of the base 101 while being formed as an integral unit therewith. The heat radiating projections 110 are arranged in line at intervals in the rear side of the tuner modules 33, respectively, so as not to block the air flow after passing through the air flow paths 76. Further, the heat radiating projections 110 are each formed to be narrower in diameter than the width of the tuner modules 33.

In the fourth embodiment as well, the heat of the tuner modules 33 and the distributor 34 propagated to the heat conductive plate 90 is released to the inside of the housing 4 via the heat sink 100 without blocking the air flow.

In the third and fourth embodiments, the radiating fins 102 and the heat radiating projections 110 are disposed in the rear side of the tuner modules 33; however the present invention is not limited to these embodiments. For example, the radiating fins 102 and the heat radiating projections 110 may be disposed in the rear side of the air flow paths 76. In this case, the air flow having passed the air flow paths 76 is allowed to blow actively onto the radiating fins 102 and the heat radiating projections 110.

Further, the electronic device of this invention is not limited to a television external device, but is applicable similarly to some other devices such as personal computers and servers.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device comprising:
a housing;
a board housed in the housing;
a plurality of first modules mounted on the board at intervals, the plurality of first modules generating heat while in operation and projecting from the board;
at least one air flow path formed between an adjacent pair of respective two of the first modules;
a second module mounted on the board, the second module being adjacent to one end side of the first modules across the air flow path and having a projecting height from the board lower than that of the first modules; and
a fan configured to create an air flow inside the housing from the first modules towards the second module.

2. The electronic device of claim 1, wherein
the board comprises a flat mount surface;
the plurality of first modules are mounted on the board in a vertical posture that the first modules stand up on the mount surface; and
the second module is mounted on the board in a horizontal posture along the mount surface.

3. The electronic device of claim 2, wherein
the plurality of first modules each comprise a heat generating member and a cover configured to contain the heat generating member and thermally connected to the heat generating member; and
the cover is exposed to the air flow path.

4. The electronic device of claim 3, wherein
the second module is disposed on a downstream of the air flow path along the air flowing direction.

5. An electronic device comprising:
a housing;
a board housed in the housing;
a plurality of first modules mounted on the board at intervals in a vertical posture, the plurality of first modules generating heat while in operation and projecting from the board;
at least one air flow path formed between an adjacent pair of respective two of the first modules;
a second module mounted on the board in a horizontal posture, the second module being connected to one end side of the first modules across the air flow path and having a projecting height from the board lower than that of the first modules;
a heat conductive member configured to thermally connect the plurality of first modules and the second module to each other; and
a fan configured to create an air flow inside the housing from the first modules towards the second module.

6. The electronic device of claim 5, wherein
the heat conductive member comprises a first portion thermally connected to the plurality of first modules and a second portion thermally connected to the second module; and
the first portion comprises a through hole communicating to a downstream end of the air flow path.

7. The electronic device of claim 6 further comprising a heat sink thermally connected to the heat conductive member.

8. The electronic device of claim 7, wherein
the heat sink is thermally connected to the second portion of the heat conductive member, and is disposed on a downstream of the through hole of the heat conductive member along the air flowing direction.

9. The electronic device of claim 8, wherein
the plurality of first modules each comprise a heat generating member and a cover configured to contain the heat generating member and thermally connected to the heat generating member; and
the cover is exposed to the air flow path.
